(19) United States
(12) Patent Application Publication
(10) Pub. No.: US 2026/0271231 A1
(43) Pub. Date: Sep. 10, 2026

(54) COOLING DEVICE FOR SWITCHGEAR CABINET AIR CONDITIONING AND A CORRESPONDING SWITCHGEAR CABINET ARRANGEMENT

(71) Applicant: RITTAL GMBH & CO. KG, Herborn (DE)

(72) Inventors: Jörg KNETSCH, Ehringshausen (DE); Christoph WASCHKE, Herborn (DE); Juan Carlos CACHO ALONSO, Braunschweig (DE)

(21) Appl. No.: 18/873,555

(22) PCT Filed: Jun. 16, 2023
(86) PCT No.: PCT/DE2023/100454

§ 371 Date: Dec. 10, 2024

(30) Foreign Application Priority Data
Jul. 5, 2022 (DE) 10 2022 116 777.1

(51) Int. Cl. H05K 7/20; H02B 13/035

(52) U.S. Cl. CPC H05K 7/20309; H02B 13/035; H05K 7/20318

(57) ABSTRACT

A cooling device for switchgear cabinet air conditioning, wherein the cooling device has a primary circuit which has a combustible refrigerant and has a condenser which is arranged in an external air circuit of the cooling device, and wherein the cooling device has an evaporator in an internal air circuit which is fluidically isolated from the external air circuit, wherein the cooling device has a secondary circuit which has a non-combustible refrigerant and which has the evaporator and a liquid-liquid heat exchanger which is arranged in the external air circuit and with which heat is transferred from the non-combustible refrigerant to the combustible refrigerant. A corresponding switchgear cabinet arrangement is also described.

### CROSS-REFERENCE TO RELATED APPLICATIONS

This application is a U.S. National Phase Application under 35 U.S.C. 371 of International Application No. PCT/DE 2023/100454, filed on Jun. 16, 2023, which claims the benefit of German Patent Application No. 10 2022 116 777.1, filed on Jul. 5, 2022. The entire disclosures of the above applications are incorporated herein by reference.

### BACKGROUND

This section provides background information related to the present disclosure which is not necessarily prior art.

### Technical Field

The invention is based on a cooling device for switchgear cabinet air conditioning and a corresponding switchgear cabinet arrangement, wherein the cooling device has a primary circuit which has a combustible coolant and has a condenser which is arranged in an external air circuit of the cooling device. The cooling device also has an evaporator in an internal air circuit which is fluidically isolated from the external air circuit. The internal air circuit can have an air inflow opening and an air outflow opening which are open into the interior space of a switchgear cabinet housing. The external air circuit can be open with its air inlet and its air outlet to the surroundings of the cooling device or the switchgear cabinet arrangement. The external air circuit can thus have ambient air flowing through it and for this purpose have a fan. The air flowing through the external circuit can act upon the condenser which is configured for this purpose, for example, as an air-liquid heat exchanger. In the internal air circuit, the air circulated through the internal air circuit can act upon an evaporator arranged in the internal air circuit. The evaporator can be designed as an air-liquid heat exchanger. A cooling device of this type is known from DE 10 2018 109 604 A1.

### Discussion

Directive 2006/42/EC (Machine Directive) requires that there is no risk of explosion and fire from gases used in a machine, wherein it is to be assumed that individual components fail. If, therefore, in the case of a switchgear cabinet cooling device, a refrigerant-carrying part has an assumed leakage, it is to be assumed that combustible gas (refrigerant) passes into the switchgear cabinet and can ignite there at internal fittings which ignite arcs during operation. Without a safety function which reliably prevents this, switchgear cabinet cooling devices which use combustible refrigerants cannot meet the machine directive or be operated with the necessary safety for the end user.

The switchgear cabinet arrangements known from the prior art have the disadvantage that they are comparatively complex to implement, since, for example, different, actively driven closing members are required and have to be activated in the event of a detected leakage and/or in the event of entry of a combustible refrigerant into the interior of the switchgear cabinet, for example in order to close a partition between the internal circuit of the cooling device and the switchgear cabinet interior, so that no (further) refrigerant can pass into the interior of the switchgear cabinet.

### SUMMARY

This section provides a general summary of the disclosure and is not a comprehensive disclosure of its full scope or all of its features.

It is therefore one aspect of the invention to further develop the cooling device described at the outset in such a way that it combines all the safety measures required according to the machine directive and thus no adaptations to the rest of the switchgear cabinet arrangement, in particular to the switchgear cabinet housing, are required.

Accordingly, it is provided in the case of the cooling device that it has a secondary circuit which has a non-combustible refrigerant and which has the evaporator and a liquid-liquid heat exchanger which is arranged in the external air circuit and with which heat is transferred from the non-combustible refrigerant to the combustible refrigerant.

The separation of the cooling circuit of the cooling device into a primary circuit and a secondary circuit, of which the secondary circuit has a non-combustible refrigerant, ensures, even in the event of a leakage of one of the two refrigerant circuits, that no combustible refrigerant can pass into the internal air circuit and thus into the interior space of a switchgear cabinet housing.

The liquid-liquid heat exchanger can be a condenser of the secondary circuit and an evaporator of the primary circuit. The liquid-liquid heat exchanger can be designed as a plate heat exchanger.

The primary circuit can be designed as an active compressor refrigeration circuit with a compressor and an expansion member.

The primary circuit can be arranged in the cooling device in a manner fluidically isolated from the internal air circuit.

The primary circuit can be completely ventilated to the surroundings of the cooling device. In particular, the primary circuit can be arranged completely in the external air circuit.

The secondary circuit can be a passive refrigerant circuit, preferably a refrigerant circuit in natural circulation, driven by a geodetic height difference. The secondary circuit can be designed, for example, as a heat pipe or comprise a heat pipe. The non-combustible refrigerant can be or comprise, for example, carbon dioxide.

The cooling device can also comprise a tertiary circuit, in which the condenser of the primary circuit is the condenser of the tertiary circuit and the evaporator of the secondary circuit is the evaporator of the tertiary circuit.

The condenser of the primary circuit and/or of the tertiary circuit can be a dual-circuit air-liquid heat exchanger with two liquid-conducting lines fluidically isolated from one another.

The evaporator of the secondary circuit and of the tertiary circuit can be a dual-circuit air-liquid heat exchanger with two liquid-conducting lines fluidically isolated from one another.

The tertiary circuit can comprise or be a non-combustible refrigerant, for example carbon dioxide.

The tertiary circuit can be a passive refrigerant circuit, preferably a refrigerant circuit in natural circulation, driven by a geodetic height difference, and the tertiary circuit can be or comprise, for example, a heat pipe.

In the cooling device, a fan can be arranged in each case in the external air circuit and in the internal air circuit. With the fan in the external circuit, the condenser can be acted upon by the air conveyed through the external air circuit. With the fan in the internal circuit, the evaporator can be acted upon by the air conveyed through the internal air circuit.

In a switchgear cabinet arrangement comprising a switchgear cabinet housing and a cooling device of the type described above, ambient air of the switchgear cabinet arrangement is conveyed through the external air circuit and air received in an interior space of the switchgear cabinet housing is conveyed through the internal air circuit. The internal air circuit and the external air circuit can be fluidically isolated from one another, so that no air exchange can take place between the external air circuit and the internal air circuit.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

Exemplary embodiments of the invention are explained with reference to the following figures. In the figures:

FIG. 1 shows a schematic cross-sectional view of a switchgear cabinet arrangement; and

FIG. 2 shows a block diagram of a cooling device according to the invention.

### DETAILED DESCRIPTION

Example embodiments will now be described more fully with reference to the accompanying drawings.

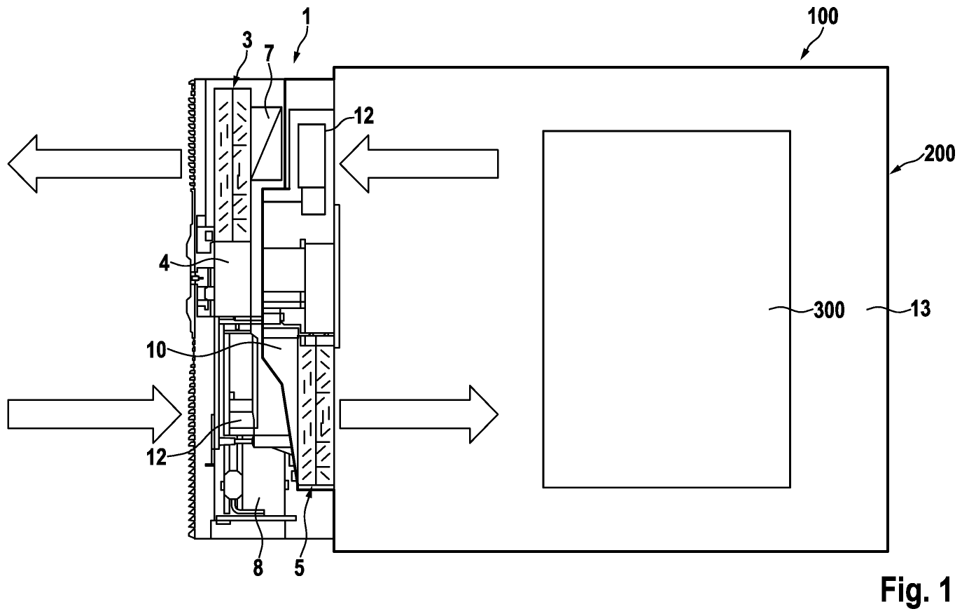

FIG. 1 shows an exemplary embodiment of a switchgear cabinet arrangement 100 with a switchgear cabinet housing 200 and a cooling device 1 mounted thereon in a side part. Arranged in the switchgear cabinet housing 200 are heat-emitting and possibly arc-generating components 300 at which a combustible refrigerant which accumulates in the interior space 13 of the switchgear cabinet housing 200 can ignite, for example at an arc which is generated during a switching operation of a switching device 300.

The cooling device 1 has an internal air circuit 10 through which the air received in the interior space 13 of the switchgear cabinet housing 200 is transported with the aid of a fan 12. While the heated air is introduced into the internal air circuit 10 in an upper region of the switchgear cabinet housing 200, it flows out of the internal circuit 10 and back into the interior space 13 of the switchgear cabinet housing 200 in a lower region of the switchgear cabinet housing 200. On its way through the internal air circuit 10, the air acts upon an evaporator 5 which is configured in the present case as an air-liquid heat exchanger of a compressor circuit, as a result of which the air cools down.

In the external air circuit 4, the cooling device 1 has a condenser 3 which is acted upon by ambient air of the switchgear cabinet arrangement 100 flowing through the external air circuit 4 and is likewise configured as an air-liquid heat exchanger.

In contrast to the cooling devices known from the prior art, in the cooling device 1 according to the invention, the evaporator 5 in the internal air circuit 1 is not fluidically connected to the condenser 3 in the external air circuit 4 via a common refrigerant circuit. Instead, a primary circuit 2 which has the condenser 3 and a secondary circuit 6 which has the evaporator 5 are provided, which are in turn thermally coupled to one another in a manner fluidically isolated from one another via a liquid-liquid heat exchanger 7.

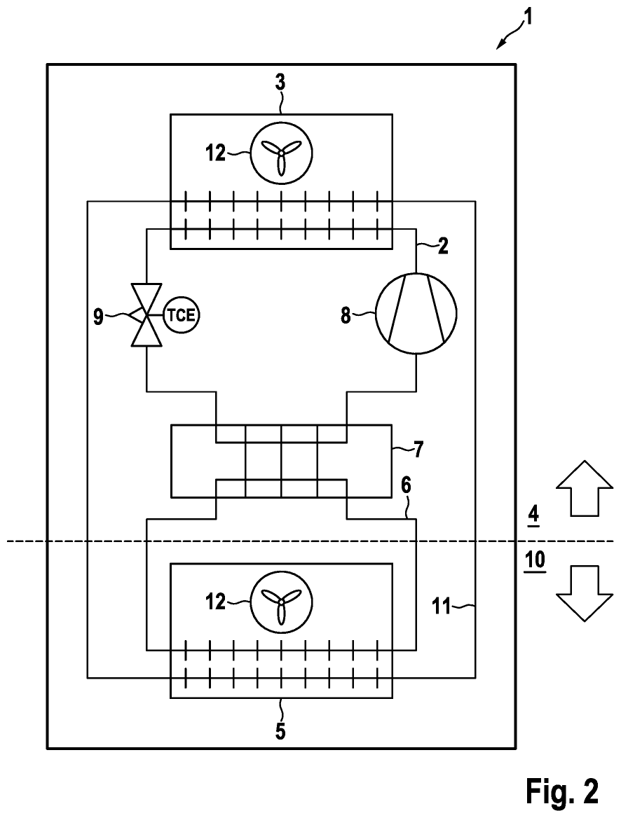

For a better understanding of the fluidic interconnection of an exemplary cooling device according to the invention, reference is made to the block diagram according to FIG. 2. Therein, the horizontal dashed line represents the airtight separation between the external air circuit 4 or the surroundings of the switchgear cabinet arrangement and the internal air circuit 10 or the interior space 13 of the switchgear cabinet housing. Accordingly, a primary circuit 2 which is designed as a compressor circuit with a compressor 8 and an expansion member 9 is arranged completely in the external air circuit 4. Accordingly, the primary circuit 2 can comprise a combustible refrigerant, since even in the event of a leakage owing to the separation between the internal air circuit 10 and the external air circuit 4, no combustible refrigerant can enter into the internal air circuit 10 or into the interior space 13 of the switchgear cabinet housing 200 with the components 300 received therein. In the manner known from the prior art, the primary circuit 2 has an air-liquid heat exchanger which is acted upon with air by a fan 12 and has the function of a condenser. In contrast to the known cooling devices 1, the evaporator of the primary circuit 2 is a liquid-liquid heat exchanger 7, for example a plate heat exchanger, via which the primary circuit 2 is thermally coupled to a secondary circuit 6. The secondary circuit 6 has a further air-liquid heat exchanger 5 which is likewise acted upon with air by a fan 12, which air is conducted through the internal air circuit 10. The secondary circuit 6 is filled with a non-combustible refrigerant, so that refrigerant which enters into the interior space 13 and exits in the event of a leakage cannot be ignited at an arc of the components 300. With respect to the secondary circuit 6, the liquid-liquid heat exchanger 7 forms a condenser.

To further optimize the efficiency of the cooling device 1, the condenser 3 and the evaporator 5 are each of dual-circuit design, wherein in each case one of the two circuits of the condenser 3 and of the evaporator 5 forms a tertiary circuit. Both the tertiary circuit 11 and the secondary circuit 6 can preferably be designed as a refrigerant circuit in natural circulation, which is driven by a geodetic height difference. In one embodiment, the secondary circuit 6 and/or the tertiary circuit 11 can be designed as a heat pipe.

The features of the invention which are disclosed in the above description, in the drawing and in the claims can be essential both individually and in any desired combination for the realization of the invention.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-16. (canceled)

17. A cooling device for switchgear cabinet air conditioning, comprising wherein the cooling device has a primary circuit which has a combustible refrigerant and has a condenser which is arranged in an external air circuit of the cooling device, and wherein the cooling device has an evaporator in an internal air circuit which is fluidically isolated from the external air circuit, wherein the cooling device has a secondary circuit which has a non-combustible refrigerant and which has the evaporator and a liquid-liquid heat exchanger which is arranged in the external air circuit and with which heat is transferred from the non-combustible refrigerant to the combustible refrigerant, wherein the cooling device comprises a tertiary circuit, in which the condenser of the primary circuit is the condenser of the tertiary circuit and the evaporator of the secondary circuit is the evaporator of the tertiary circuit.

18. The cooling device according to claim 17, in which the liquid-liquid heat exchanger is a condenser of the secondary circuit and an evaporator of the primary circuit.

19. The cooling device according to claim 17, in which the liquid-liquid heat exchanger is designed as a plate heat exchanger.

20. The cooling device according to claim 17, in which the primary circuit is designed as an active compressor refrigeration circuit with a compressor and an expansion member.

21. The cooling device according to claim 17, in which the primary circuit is arranged in the cooling device in a manner fluidically isolated from the internal air circuit.

22. The cooling device according to claim 17, in which the primary circuit is completely ventilated to the surroundings of the cooling device.

23. The cooling device according to claim 22, in which the primary circuit is arranged completely in the external air circuit.

24. The cooling device according to claim 17, in which the secondary circuit is a passive refrigerant circuit, preferably a refrigerant circuit in natural circulation, driven by a geodetic height difference, for example a heat pipe.

25. The cooling device according to claim 17, in which the non-combustible refrigerant comprises carbon dioxide.

26. The cooling device according to claim 17, in which the condenser of the primary circuit and of the tertiary circuit is a dual-circuit air-liquid heat exchanger with two liquid-conducting lines fluidically isolated from one another.

27. The cooling device according to claim 17, in which the evaporator of the secondary circuit and of the tertiary circuit is a dual-circuit air-liquid heat exchanger with two liquid-conducting lines fluidically isolated from one another.

28. The cooling device according to claim 17, in which the tertiary circuit comprises a non-combustible refrigerant, for example carbon dioxide.

29. The cooling device according to claim 17, in which the tertiary circuit is a passive refrigerant circuit, preferably a refrigerant circuit in natural circulation, driven by a geodetic height difference, for example a heat pipe.

30. The cooling device according to claim 17, in which a fan is arranged in each case in the external air circuit and in the internal air circuit, with which fan the evaporator or the condenser is acted upon by the air conveyed through the respective air circuit.

31. A switchgear cabinet arrangement comprising a switchgear cabinet housing and a cooling device according to claim 17, wherein ambient air of the switchgear cabinet arrangement is conveyed through the external air circuit and air received in an interior space of the switchgear cabinet housing is conveyed through the internal air circuit.
